(19) United States
(12) Patent Application Publication
(10) Pub. No.: US 2004/0065471 A1
(43) Pub. Date: Apr. 8, 2004

(54) Electronic circuit board

(75) Inventors: Chak Yin Tang, Hung Hom (HK); Ka Wai Eric Cheng, Hung Hom (HK)

Correspondence Address: LEYDIG VOIT & MAYER, LTD, 700 THIRTEENTH ST. NW, SUITE 300, WASHINGTON, DC, 20005-3960, US

(73) Assignee: The Hong Kong Polytechnic University, Hung Hom (HK)

(21) Appl. No.: 10/265,200

(22) Filed: Oct. 7, 2002

(51) Int. Cl. H05K 3/02; H05K 1/00

(52) U.S. Cl. 174/250; 29/847; 29/829

(57) ABSTRACT

A circuit board is made from a polymer material and includes a predetermined portion which has magnetic or dielectric or resistive properties. The portion with the magnetic or dielectric or resistive properties is made first and arranging within a mold. A polymer is then applied to the mold to form a board incorporating the portion with the magnetic or dielectric or resistive properties.

### BACKGROUND TO THE INVENTION

1. Field of the Invention

The present invention relates to electronic circuit boards and to methods of making electronic circuit boards.

2. Background Information

Existing Printed Circuit Boards (PCBs) comprise a sheet of non-conductive material, typically fiberglass reinforced polymer, laminated with a conductive layer of copper. The copper can be laminated on both the top and bottom surfaces of the polymer sheet. Portions of the copper are removed by printing and etching to leave conductive copper tracks on the surfaces of the polymer sheet. Holes are drilled through the copper tracks and underlying mica sheet to allow connection of electronic components on the top layer and/or bottom layers on the PCB. The components are therefore connected and exposed externally on the PCB.

In modern electronic circuits a great deal of the circuitry is comprised of Integrated Circuits (ICs) soldered to the PCB. This allows for a large number of active components to be mass produced into small packages which occupies little space of the PCB surface. However, a number of passive components such as inductors and capacitors cannot be manufactured into an IC and must be mounted separately on the PCB. The problem with this is that it increases the space and electromagnetic interference due to the connection of these passive components externally.

A further problem is that the assembly procedure for the PCB is made more complex, resulting in higher manufacturing costs.

### SUMMARY OF THE INVENTION

It is an object of the present invention to provide an electronic circuit board, and a method of making said electronic circuit board, which ameliorates the above problems, or which at least provides the public with a useful alternative.

According to a first aspect of the invention there is provided a circuit board made from a polymer material wherein a predetermined portion of the board has magnetic or dielectric or resistive properties.

Preferably, the portion includes elements having the magnetic or dielectric or resistive properties bonded into the polymer material.

Preferably, the elements having magnetic properties are a metal filler comprising a ferromagnetic material.

Preferably, the metal filler comprises a combination of Cobalt and Nickel particles.

Preferably, the elements having dielectric properties are polyester and/or polypropylene.

Preferably, the elements having resistive properties are graphite and silver.

According to a second aspect of the invention there is provided a method of making a circuit board including the steps of:

making at least ore board portion compromising a polymer material having magnetic or dielectric or resistive properties,

arranging the board portion within a mold, and

applying a polymer to the mold to form a board incorporating the board portion.

Preferably, the method further includes grinding surfaces of the board to expose a surface of the broad portion.

Preferably, the method further includes the steps of applying film of copper to one or both sides of the board, and etching portions of the copper film to reveal conductive tracks on the sides of the board.

Preferably, the board portion includes elements having the magnetic or dielectric or resistive properties bonded into the polymer material.

Preferably, the elements having magnetic properties are a metal filler comprising one or more ferromagnetic materials.

Preferably, the metal filler comprises a combination of Cobalt and Nickel particles.

Preferably, the elements having dielectric properties are polyester and/or polypropylene.

Preferably, the elements having resistive properties are graphite and/or silver.

Further aspects of the invention will become apparent from the following description, which is given by way of example only.

### BRIEF DESCRIPTION OF THE DRAWINGS

Embodiments of the invention will now be described with reference to the accompanying drawings in which:

FIG. 1 is a view of typical electronic circuit that is mounted on a PCB,

FIG. 2 illustrates a circuit board according to the invention,

FIG. 3 is a photo of the circuit of FIG. 1 mounted on the circuit board of FIG. 2, and

FIG. 4 are signal waveforms from the circuit of FIG. 3.

### DISCLOSURE OF INVENTION

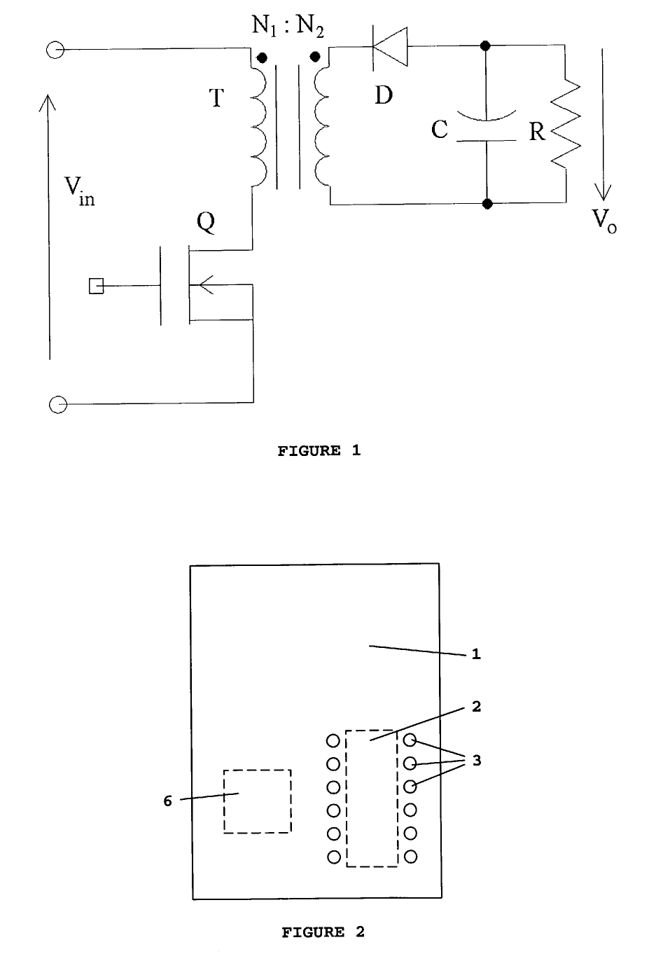

The invention will be described with reference to a flyback converter circuit as shown in FIG. 1. Operation of this simple circuit will be apparent to the skilled addressee, as will the fact that device T acts as both a transformer and inductor in the circuit. The magnetic core of the transformer/inductor T and dielectric of capacitor C in the circuit are integrated into portions of the circuit board. However, the invention can be applied to any electronic circuit which requires discrete passive components such as transformers, inductors, capacitors or resistors to be mounted on a circuit board.

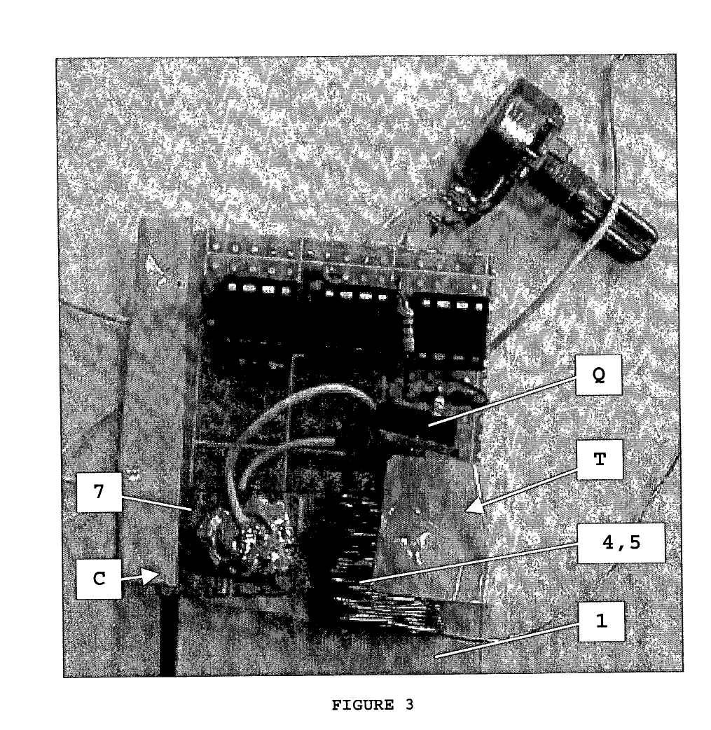

Referring to FIG. 2, a circuit board 1 is made of epoxy resin. Integrated into the epoxy board 1 is a board portion 2 having magnetic properties. The magnetic portion 2 forms a core for transformer/inductor T. A plurality of holes 3 are drilled either side of magnetic portion 2 to allow copper wire to pass in loops though the epoxy board forming first and second windings 4,5 (shown in FIG. 3) around the magnetic portion 2. Also integrated into the epoxy board 1 is a second board portion 6 having dielectric properties. The second board portion 6 forms the dielectric of a capacitor C.

In common with known PCBs the epoxy board 1 has etched copper tracks (not shown) which form the circuit wiring conductors. Also, etched copper areas 7 in juxtaposition the dielectric portion 6 provide plates for capacitor C.

The epoxy board 1 is drilled for the components Diode D, Resistor R, semiconductor switch Q and switching IC (not shown) in the same manner as known PCBs.

An illustration of the completed flyback converter on the epoxy board 1 is shown in FIG. 3. The windings 4,5 of transformer/inductor T and parallel plate 7 of capacitor C are evident. The magnetic and dielectric materials of the transformer/inductor T and capacitor C are integrated into portions 2, 6 of the circuit board 1.

The epoxy board 1 is made by first forming the magnetic and dielectric portions 2, 6 in the required shape. The shape is designed according to the packaging and the component parameter (inductance and capacitance) required. The only restrictive condition on the shape is that the preformed magnetic and dielectric portions 2, 6 must be no thicker that the proposed thickness of the epoxy board 1. In the preferred embodiment this is 2 mm.

The portions 2, 6 are made slightly thicker initially as the epoxy board 1 is ground or milled to the finished thickness after it is formed.

A composite magnetic material for the magnetic portion 2 is produced by adding a metal powder filler to epoxy resin and two additives. The epoxy resin is 4,4-isopropylidenediphend epichlorohydrin resin and the two additives are alkyl glycidyl ether and poly-acrylate ether. The cross-linking agent (hardener) for the epoxy resin contains diethylenetriamine and 2-hydroxyethydiethylenetriamine, One part of the hardener is mixed with five parts of epoxy resin.

The metal powder filler comprises spherical Cobalt and Nickel particles. The particles are in the range of 1-18 micrometers in diameter. The surface of the particles is treated with a titanic coupling agent to enhance disbursement through the epoxy resin and increase the bond strengthen between the particles and resin.

The ratio of filler particles to resin is given in the following table:

| Cobalt | | Filler | Epoxy resin |
|---|---|---|---|
| Particles | Nickel | weight-to- | weight-to- |
| (weight, | Particles | weight | weight |
| g) | (weight, g) | (%) | (%) |
| 10 | 10 | 45.0 | 55.0 |

The ration of Cobalt to Nickel particle, and filler to resin are varied to alter the magnetic properties of the composite magnetic portion 2. Further details of the composite magnetic material can be found in applicants earlier U.S. patent application Ser. No. 10/177,751 filed on Jun. 24, 2002.

The dielectric portion 6 is made of polymer with an appropriate dielectric property that gives the desired value of capacitance. In the preferred embodiment the polymer is Polyester. In alternative embodiments it may be Polypropylene or similar materials. The dielectric area, in this example, is preferably pre-molded to the required shape.

Although the present example does not consist of a resistive board portion, one can be made from a conductive polymer resin. The conductive polymer resin is made by blending conductive fillers, such as graphite powder, with a thermoplastic, such as polypropylene. The shape of the resistive area and the filled volume of the conductive filler determines the resistance of the resistive portion. Silver also makes an effective filler. The resistive portion is preferably pre-molded to the required shape.

A flat mold is used for producing the epoxy board 1. The preformed magnetic and dielectric portions 2, 6 are located in their predetermined positions within the mold and kept in place by a suitable holding means. Epoxy resin is then applied to the mold and allowed to set.

After being formed the set epoxy board 1 is ground to the desired thickness of 2 mm. The grinding exposes surfaces of the magnetic and dielectric portions 2, 6 on the upper and lower sides of the board 1. These upper and lower surfaces of the magnetic and dielectric portions 2, 6 are not, therefore, covered by epoxy resin.

Thin copper sheet is laminated on to the upper and lower sides of the board 1 in known manner. The copper surfaces are printed, etched and the board drilled in the same manner as known PCBs.

In the above described example the winding conductors of the transformer/inductor T are wires wound on after production of the circuit board. In alternative examples the winding conductors of inductors and the like are copper tracks on the magnetic portions of the board. These tracks are formed during the printing and etching of the copper layer. Linking of tracks on upper and lower sides of the magnetic portion is achieved by copper plating the inside of through-holes in known manner.

Copper “plates” over the dielectric portions of the board form capacitor plates.

In the described example epoxy resin is used to bond the composite magnetic and dielectric materials and form the neutral areas of the circuit board. However, any suitable polymer bonder may be used. The polymer bonder must be chosen to be chemically compatibility to the composite functional (magnetic, dielectric or resistive) materials. In addition, the bond strength must meet mechanical strength requirement. To achieve this, inert fillers can be blended with the polymer bonder before molding for improving dimensional stability of the board. Details of the type and quantity of fillers can be obtained from the polymer manufacturer or data sheet.

The invention can also find application in surface mount and multi-layer circuit board applications. The principle involved is the same as described here and such application is within the ability of the skilled addressee.

The circuit board according to the invention was tested to verify its usefulness. The designed circuit parameters for the test were L=7.5 μH, C=2 μF, R=185 Ω. The test parameters represent a high frequency power application, because this is more problematic than low frequency applications due to the effect of coupling and electromagnetic interference.

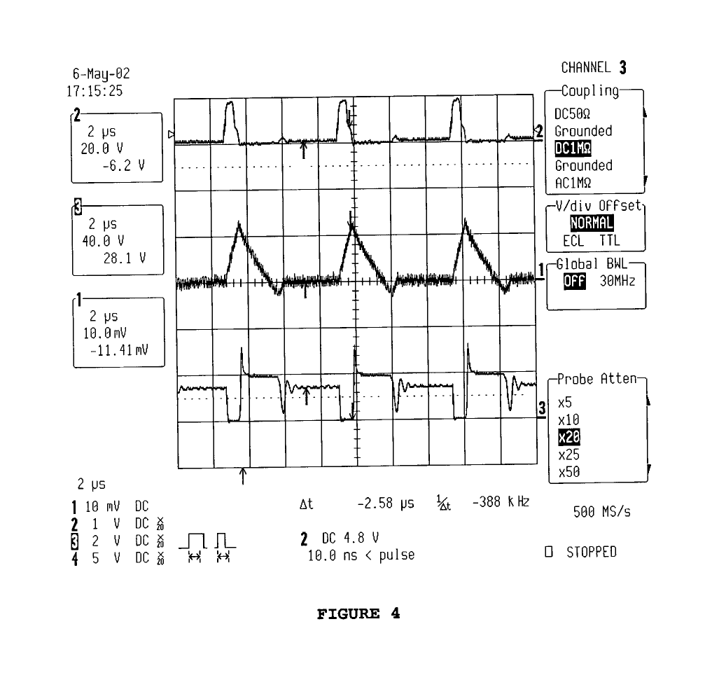

FIG. 4 shows the waveforms from the test circuit under steady-state operation. The input voltage is 29V and 0.38A. The switching frequency is 165 kHz. The measured efficiency is 70%. The measured waveforms are very clear and very little noise is present. No adverse effect has been observed. The performance is the same as for a conventional PCB mounted circuit.

The advantages of the composite circuit board are these. The circuit manufacturing process is simpler because the passive components are embedded in the circuit board so the circuit can be assembled in fewer steps, Polymer bonded magnetic materials enable high permeability to be obtained. Higher relative inductances can be achieved, and inductor size can therefore reduced. The electrical connection can be established by copper tracks that can be programmed into printing and etching equipment. Some connections can be made by wirebonding, which can also be programmed. The whole process has a reduction in cost, time and produce size. Electromagnetic interference and coupling are reduced.

Where in the foregoing description reference has been made to integers or elements having known equivalents then such are included as if individually set forth herein.

Embodiments of the invention have been described, however it is understood that variations, improvements or modifications can take place without departure from the spirit of the invention or scope of the appended claims.

What is claimed is:

1. A circuit board made from a polymer material wherein a predetermined portion of the board has magnetic or dielectric or resistive properties.

2. The circuit board of claim 1 in which the predetermined portion includes elements having the magnetic or dielectric or resistive properties bonded into the polymer material.

3. The circuit board of claim 2 in which the elements having magnetic properties are a metal filler comprising a ferromagnetic material.

4. The circuit board of claim 3 in which the metal filler comprises a combination of Cobalt and Nickel particles.

5. The circuit board of claim 2 in which the elements having dielectric properties are polyester and/or polypropylene.

6. The circuit board of claim 2 in which the elements having resistive properties are graphite and silver.

7. A method of making a circuit board including the steps of:
making at least one board portion compromising a polymer material having magnetic or dielectric or resistive properties,
arranging the board portion within a mold, and
applying a polymer to the mold to form a board incorporating the board portion.

8. The method of claim 7 including a step of grinding surfaces of the board to expose a surface of the broad portion.

9. The method of claim 7 including the steps of applying film of copper to one or both sides of the board, and etching portions of the copper film to reveal conductive tracks on the sides of the board.

10. The method of claim 7 in which the board portion includes elements having the magnetic or dielectric or resistive properties bonded into the polymer material.

11. The method of claim 7 in which the elements having magnetic properties are a metal filler comprising one or more ferromagnetic materials.

12. The method of claim 7 in which the metal filler comprises a combination of Cobalt and Nickel particles.

13. The method of claim 7 in which the elements having dielectric properties are polyester and/or polypropylene.

14. The method of claim 7 in which the elements having resistive properties are graphite and/or silver.
